(19) United States
(12) Patent Application Publication
(10) Pub. No.: US 2018/0292244 A1
(43) Pub. Date: Oct. 11, 2018

(54) EXTENSIBLE ENVIRONMENTAL DATA COLLECTION PACK

(71) Applicant: GrayWolf Sensing Solutions, LLC, Shelton, CT (US)

(72) Inventors: William F. VanWart, Austin, TX (US); Richard T. Stonier, Shelton, CT (US); John Coffey, Annacotty (IE)

(21) Appl. No.: 15/942,264

(22) Filed: Mar. 30, 2018

Related U.S. Application Data
(60) Provisional application No. 62/482,774, filed on Apr. 7, 2017.

(51) Int. Cl. G01D 21/02; H03M 7/24; G06F 5/01; H03M 1/06

(52) U.S. Cl. CPC G01D 21/02; H03M 1/0617; G06F 5/01; H03M 7/24

(57) ABSTRACT

An environmental data collection system includes a controller and one or more smart sensors coupled to the controller, each smart sensor comprising a memory, the memory configured to store configuration and calibration data for each data channel output by sensing devices of the smart sensors.

This application claims the benefit of U.S. Provisional Application No. 62/482,774, filed on 7 Apr. 2017, incorporated by reference in its entirety.

### FIELD

The disclosed exemplary embodiments are directed to environmental probes and sensors, and in particular, to an extensible environmental data collection pack having a controller, one or more self-configuring smart probes, and a set of smart sensors.

### BACKGROUND

Environmental instruments are capable of measuring various parameters, including amounts of volatile organic compounds, toxic gasses, sound, relative humidity, light, etc. However, while sensors for these different parameters may be smart, that is, may be capable of processing sensor signals to achieve a specific type of output, smart sensors have different form factors, may utilize different communication protocols, and may produce different types of outputs. There is a need for an extensible environmental data collection pack that supports a number of smart sensors and one or more smart probes and overcomes the limitations of the prior art.

### SUMMARY

The disclosed embodiments are directed to a controller, a set of smart sensors, and optionally one or more smart probes. The smart sensors and smart probes, under control of the controller, communicate using a common communication protocol and provide environmental data in a common, normalized format.

The disclosed embodiments are also directed to an environmental data collection system including a controller and one or more smart sensors coupled to the controller, each smart sensor having a memory, the memory configured to store configuration and calibration data for each data channel output by sensing devices of the smart sensors.

The one or more smart sensors may each include a sensor communication interface for communicating with the controller.

The configuration and calibration data may include conditioning information for converting the data channel outputs to a fixed bit format.

The fixed bit format may be a 24 bit format.

The one or more smart sensors may include a signal processor configured to use the configuration and calibration data for processing data from each data channel output of the sensing devices, and to use the conditioning information to convert the sensor data for each data channel output to a fixed bit format.

The signal processor may be an analog to digital converter.

The one or more smart sensors may include a microcontroller configured to use the configuration and calibration data for processing data from each data channel output of the sensing devices, and to use the conditioning information to convert the sensor data for each data channel output to a fixed bit format.

The controller may include a microprocessor and a memory including computer program code, where executing the computer program code by the microprocessor causes the controller to use the configuration and calibration data for processing data from each data channel output of the sensing devices, and to use the conditioning information to convert the sensor data for each data channel output to a fixed bit format.

The environmental data collection system may also include one or more self-configuring smart probes.

The controller may include a communication interface to one or more of a wide area or other network, a cloud service, and a building automation system.

The disclosed embodiments are further directed to a method of collecting environmental data, including using a controller to operate one or more smart sensors, and using a memory on each smart sensor to store configuration and calibration data for each data channel output by sensing devices of each smart sensors.

The one or more smart sensors may each include a sensor communication interface for communicating with the controller.

The configuration and calibration data may include conditioning information for converting the data channel outputs to a fixed bit format.

The fixed bit format may be a 24 bit format.

The method may include using a signal processor of the one or more smart sensors to use the configuration and calibration data for processing data from each data channel output of the sensing devices, and to use the conditioning information to convert the sensor data for each data channel output to a fixed bit format.

The signal processor may be an analog to digital converter.

The method may further include using a microcontroller of the one or more smart sensors to use the configuration and calibration data for processing data from each data channel output of the sensing devices; and to use the conditioning information to convert the sensor data for each data channel output to a fixed bit format.

The controller may include a microprocessor and a memory including computer program code, and the method may further include executing the computer program code by the microprocessor to cause the controller to use the configuration and calibration data for processing data from each data channel output of the sensing devices, and to use the conditioning information to convert the sensor data for each data channel output to a fixed bit format.

### BRIEF DESCRIPTION OF THE DRAWINGS

FIG. 1 shows a schematic illustration of an exemplary extensible environmental data collection pack 100 according to the disclosed embodiments; and

FIG. 2 shows an exemplary block diagram of a controller according to the disclosed embodiments;

FIGS. 3A, 3B, and 4 shows schematic illustrations of general embodiments of smart sensors according to the present disclosure;

FIG. 5 shows a schematic illustration of an exemplary sound level smart sensor according to the disclosed embodiments; and

FIG. 6 shows a schematic illustration of an exemplary particle matter smart sensor according to the disclosed embodiments;

FIG. 7 shows a schematic illustration of an exemplary electrochemical smart sensor according to the disclosed embodiments;

FIG. 8 shows a schematic illustration of an exemplary lux smart sensor according to the disclosed embodiments; and

FIG. 9 shows a schematic illustration of an exemplary smart probe according to the disclosed embodiments.

### DETAILED DESCRIPTION

The aspects and advantages of the exemplary embodiments will become apparent from the following detailed description considered in conjunction with the accompanying drawings. It is to be understood, however, that the drawings are designed solely for purposes of illustration and not as a definition of the limits of the invention, for which reference should be made to the appended claims. Additional aspects and advantages of the invention will be set forth in the description that follows, and in part will be obvious from the description, or may be learned by practice of the invention. Moreover, the aspects and advantages of the invention may be realized and obtained by means of the instrumentalities and combinations particularly pointed out in the appended claims.

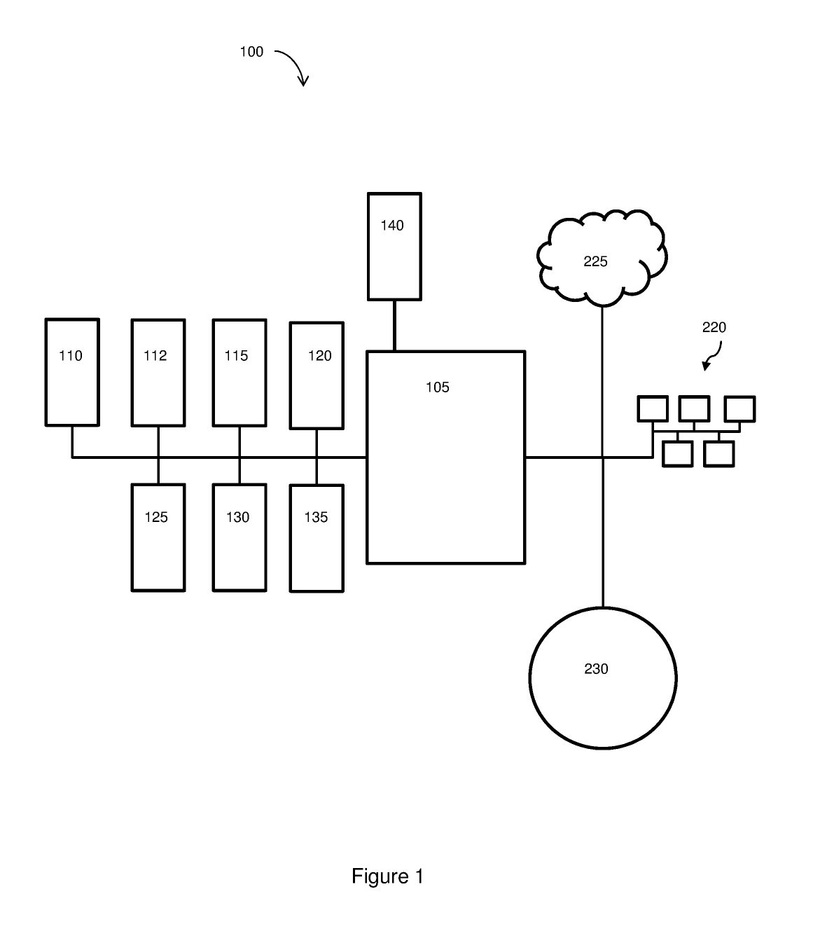

FIG. 1 shows a schematic illustration of an exemplary system 100 according to the disclosed embodiments. The system 100 may include at least one controller 105, one or more smart sensors 110, 112, 115, 120, 125, 130, 135 and optionally one or more smart probes 140. The controller 105 may be connected to one or more of a wide area or other network 220, a cloud service 225, and a building automation system 230. Additionally, the system 100, could be connected to another system 100 with the same or different configuration of smart sensors and smart probes. In some embodiments, an exemplary system 100 may be referred to as a “pack” to indicate that the controller 105, any sensors, and the smart probe, if present, operate as a unit.

It should be understood that system 100 may have any number of configurations. For example, in a first configuration, the system 100 may include a particulate matter smart sensor 125, described below, the controller 105, and a smart probe 140. In a second configuration, the system 100 may include a sound level smart sensor 120, described below, the controller 105, and a smart probe 140. In a third configuration, the system may include a lux smart sensor, described below, the controller 105, and a smart probe. It should also be understood that multiple systems 100 may operate independently or may be linked together with one of the linked systems operating as a master controller.

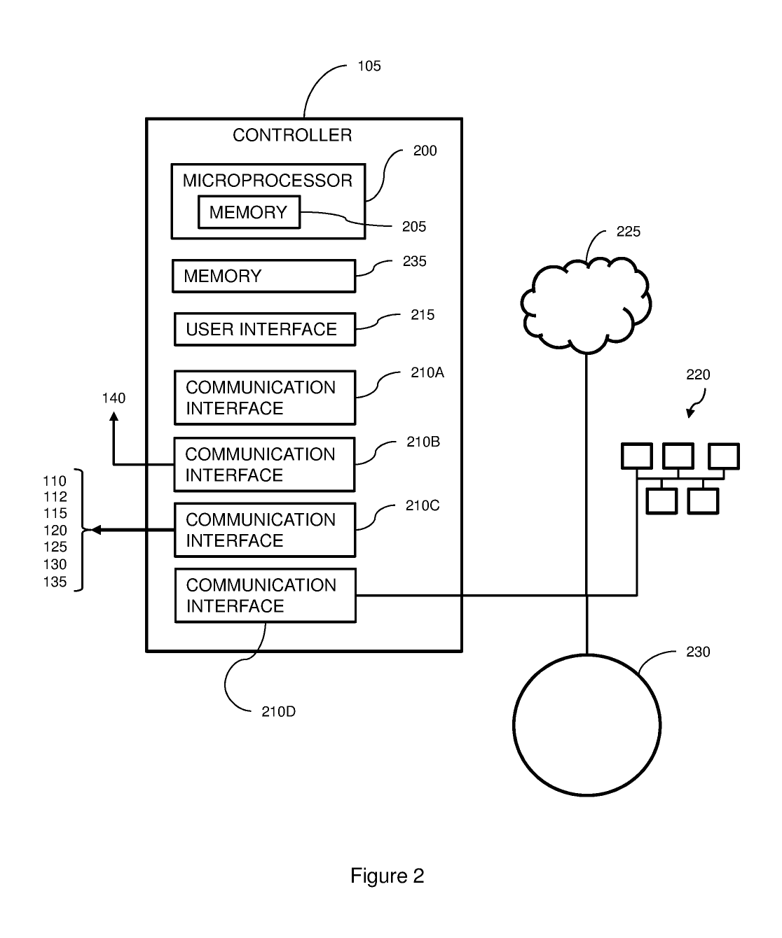

FIG. 2 shows an exemplary block diagram of the controller 105. The controller 105 may include a microprocessor 200 with memory 205 which may be onboard or embedded, a number of communication interfaces 210A, 210B, 210C, 210D, a user interface 215, and an external memory 235.

The microprocessor 200 may be implemented using any suitable computing device, for example, a microcontroller or a Computer On Module (COM). The microprocessor 200 may include flash memory, non-volatile memory, internal registers, and a plurality of I/O lines, and may be capable of running an operating system such as Windows Embedded, LINUX, Android, or any other suitable operating system.

The onboard or embedded memory 205 may include magnetic media, semiconductor media, optical media, or any media which is readable by the microprocessor 200 and may store computer readable program code, that when executed by the microprocessor 200, causes the controller to carry out and perform the processes described herein. The onboard or embedded memory 205 may also store programs for the microprocessor 200 and for controllers that may be utilized on the individual smart sensors 110, 115, 120, 125, 130, 135 and the smart probe 140, and configuration data for the smart sensors 110, 112, 115, 120, 125, 130, 135 and the smart probe 140. The controller 105 may be operable to receive data from the smart sensors 110, 112, 115, 120, 125, 130, 135 and smart probe 140 and store the data in the onboard or embedded memory 205. The controller 105 may also be operable to receive audio and text notes, documents, and video information through the user interface 215 and communication interfaces, e.g. 210D, and store them in the onboard or embedded memory 205.

The communication interfaces 210A, 210B, 210C, 210D may include one or more of a WiFi (IEEE 802.11) wireless interface, a Bluetooth (IEEE 802.15) wireless interface, a Universal Serial Bus (USB) interface, an RS 232 serial communication interface, a Modbus interface, or any other communication interface suitable for transmitting, receiving, or exchanging data. At least one of the communication interfaces, for example, communication interface 210C, may provide a communication path to the one or more smart sensors 110, 112, 115, 120, 125, 130, 135. At least one of the communication interfaces, for example, communication interface 210B, may provide a communication path to the smart probe 140. Furthermore, at least one of the communication interfaces, for example, communication interface 210D, may provide a communication path to one or more of a wide area or other network 220, a cloud service 225, and a building automation system 230, any of which may provide programming, data, and other information to the controller 105. In one or more embodiments, the network 220 or cloud service 225 may provide programs, parameters and other data for configuring the smart sensors 110, 112, 115, 120, 125, 130, 135, the smart probe 140, or both. In some embodiments, the controller 105 may send data from one or more of the smart sensors 110, 112, 115, 120, 125, 130, 135 and the smart probe 140 to any of the network 220, a cloud service 225, and building automation system 230.

The user interface 215 may include any number of input and output devices including those which may operate to allow input to the controller 105 and provide output from the controller 105. For example, the user interface 215 may include a keyboard and a microphone for entering commands and data, and a display and speaker for providing information to a user. The user interface 215 may be capable of providing the contents of the onboard or embedded memory 205 to a user, including for example, displaying the programs for the microprocessor 200 and for the smart sensor and smart probe controllers, data from the smart sensors 110, 112, 115, 120, 125, 130, 135 and smart probe 140, and displaying or playing any of the stored audio and text notes, documents, and video information. In at least one embodiment, the user interface 215 may include a liquid crystal or light emitting diode display. In some embodiments, the display may be a touch sensitive display to allow input directly through the display. Some embodiments of the controller 105 may be configured without a user interface 215 and may exchange information through the communication interface 210D.

The external memory 235 may also include magnetic media, semiconductor media, optical media, or any media which is readable by the microprocessor 200 and may store configuration and calibration data that may be specific to the types of smart sensors 110, 112, 115, 120, 125, 130, 135 and the configuration of the smart probe 140. The external memory 235 may also store logged data collected from the smart sensors 110, 115, 120, 125, 130, 135 and the smart probe 140, which may be provided to a user or downloaded to any of the network 220, cloud service 225, and building automation system 230.

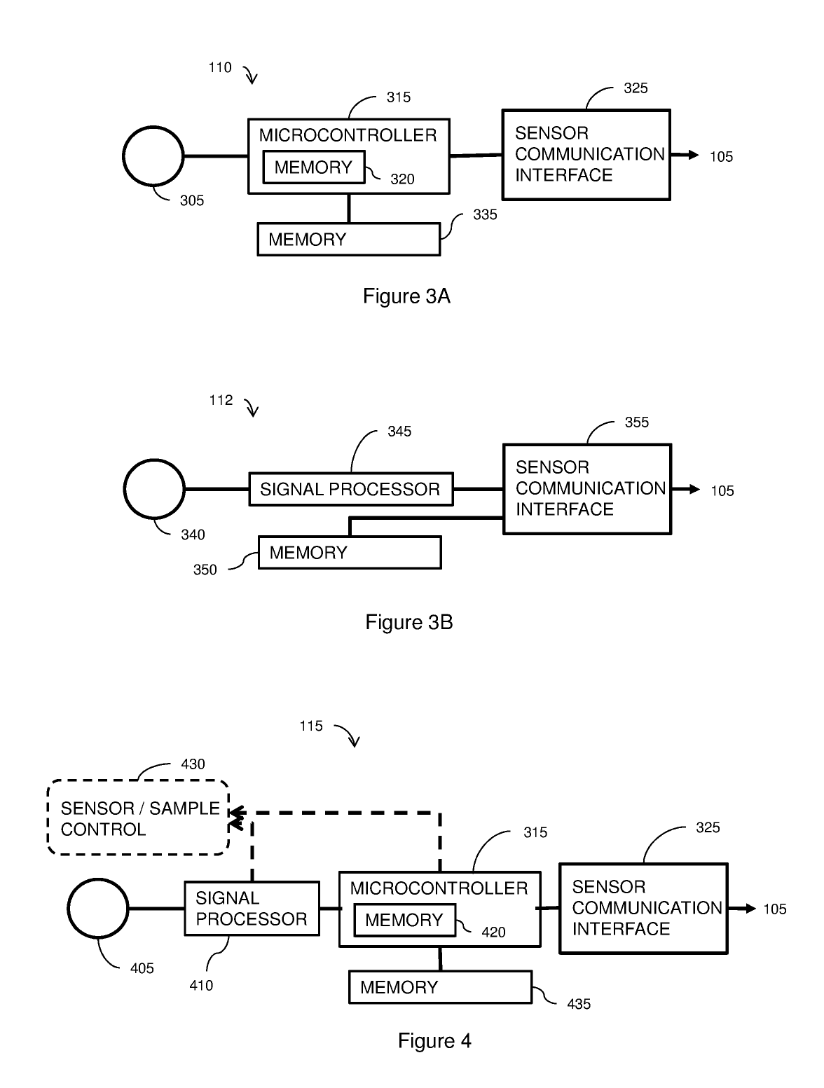

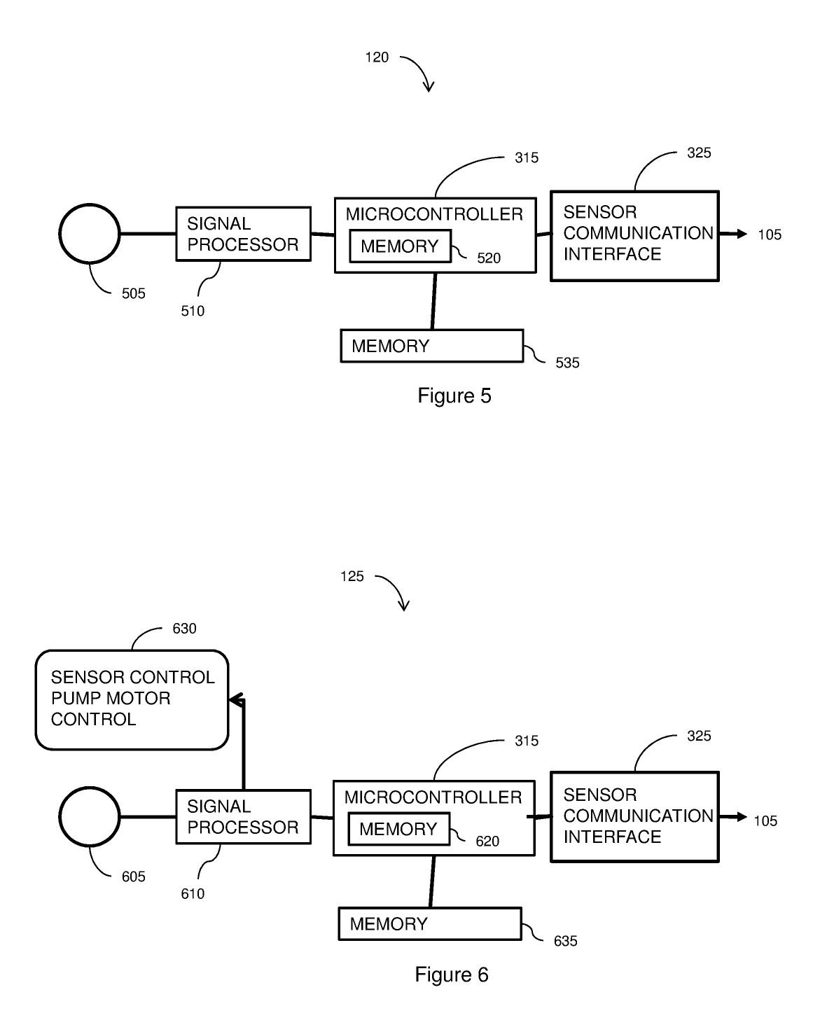

FIGS. 3A, 3B, and 4 illustrate general embodiments 110, 112, 115 of the smart sensors according to the present disclosure, while FIGS. 5-8 illustrate exemplary smart sensors 120, 125, 130, 135 for specific applications.

FIG. 3A shows an exemplary smart sensor 110. The smart sensor 110 may include a sensing device 305, microcontroller 315 with on board or embedded memory 320, and a sensor communication interface 325. The sensing device 305 may include any suitable environmental sensor that provides a digital output that, if required, may be processed directly by the microcontroller 315. The onboard or embedded memory 320 may include programming information for causing the microcontroller 315 to control the operation of the sensing device, to process the data from the sensing device 305, and to convert the data to a common format, for example, having a fixed number of bits. Some embodiments may utilize a normalized 24 bit format.

The smart sensor 110 may also include an external memory 335 with specific addresses or memory blocks for storing configuration and calibration data, for example, the status of components of the smart sensor, for example, a power status and battery level, a model number, an amount of time since power on, a type of electronics present on board, the particular sensing capabilities, and the available operational memory in external memory 335. The external memory 335 may also include specific addresses for storing configuration data about the smart sensor 110, for example, sensing device names, serial numbers, and install dates, sensing device calibration data, constants, set points, calibration location, calibration date, calibration technician, the number of data channels returned by the sensing device 305, and characteristics of each data channel, such as sensing technology, sensor type, serial numbers, and data encoding techniques. The configuration and calibration data may also include a code, algorithm, or other conditioning information for converting the output of the data channels to a fixed number of bits. The external memory 335 may also store the time as updated by a real time clock and the status of peripheral devices, such as pumps, fans, and communication network interfaces.

The microcontroller 315 may be implemented using any suitable computing device, for example, a RISC single chip microcontroller with a modified Harvard architecture, and on board flash memory. The sensor communication interface 325 may include one or more of a Universal Serial Bus (USB) interface, an RS 232 serial communication interface, an Inter-Integrated Circuit (I2C) bus interface, a Modbus interface, or any other wired communication interface suitable for transmitting, receiving, or exchanging data.

FIG. 3B shows another exemplary smart sensor 112. The smart sensor 112 may include a sensing device 340, a signal processor 345, an external memory 350 with the specific addresses or memory blocks for storing the configuration and calibration data as described above for external memory 335, and a sensor communication interface 325. In this embodiment, the signal processor 345 and external memory 350 may be accessible by the controller 105 through the sensor communication interface 325.

The sensing device 340 may include any suitable environmental sensor, for example, a sound sensing element, a laser detector, Pt100 or other sensor, capacitive or other % RH sensor, PID or other sensor for volatile organic compounds, pellister or other sensor for LEL/flammables, colorimetric/photometric sensor, NDIR, electrochemical sensor, or light sensor. In some embodiments, the sensing device 340 may provide an analog current or voltage output, while in other embodiments the sensing device 340 may provide a digital output. The signal processor 345 may include one or more of any suitable processing functions, for example, a digital signal processor, a digital or analog filtering function, a digits or analog scaling function, an averaging function, an amplifier, a counter, and an A/D converter. The signal processor 345 may generally output data in a common format, for example, a fixed bit format, and as a further example, a normalized 24 bit representation of the output of the sensing device 340.

FIG. 4 shows yet another exemplary smart sensor 115. The smart sensor 115 may include a sensing device 405, a signal processor 410, a microcontroller 315 with on board or embedded memory 420, and a sensor communication interface 325. The exemplary smart sensor 115 may optionally include control circuitry 430 for controlling the sensing device 405, for example, by setting a sensor sampling rate.

The sensing device 405 may include any suitable environmental sensor, for example, a sound sensing element, a laser detector, Pt100 or other sensor, capacitive or other % RH sensor, PID or other sensor for volatile organic compounds, pellister or other sensor for LEL/flammables, colorimetric/photometric sensor, NDIR, electrochemical sensor, or light sensor. In some embodiments, the sensing device 405 may provide an analog current or voltage output, while in other embodiments, the sensing device 405 may provide a digital output. The signal processor 410 may include one or more of any suitable processing functions, for example, a digital signal processor, a digital or analog filtering function, a digits or analog scaling function, an averaging function, an amplifier, a counter, and an A/D converter. The onboard or embedded memory 420 may include programming information for causing the microcontroller 315 to control the operation of the signal processor to process data specific to the particular sensing device, to further process the data from the signal processor 410 and to convert the data to a common format, for example, a fixed bit format, or a normalized 24 bit representation. The smart sensor 115 may also include an external memory 435 with the specific addresses or memory blocks for storing the configuration and calibration data as described above for external memory 335.

The smart sensors of the disclosed embodiments may include one or more sound level sensors, particle matter detectors, electrochemical sensors, lux sensors, Photo-Ionization Detector (PID) sensors, CO₂ Non-Dispersive Infra-Red (NDIR) sensors, sensor for flammables, Colorimetric/Photometric sensors and any other environmental sensors that may measure relative humidity, temperature, or barometric pressure, light, radiation, sound, combustible gas or solvents, and any other suitable environmental parameters.

FIG. 5 shows an implementation of a sound level smart sensor 120. In this embodiment, the sensing device may be a sound sensing element 505, for example, a microphone. The signal processor 510 may include an amplifier, a filter, and an A/D converter. The on board or embedded memory 520 may include programs and instructions that cause the processor 315 to control the operation of the signal processor 510, including the amplifier, filter, and A/D converter, to process data specific to the sound sensing element 505, to further process the data from the signal processor 510, and to convert the data to a fixed bit format such as the normalized 24 bit format mentioned above.

Similar to the other smart sensors described herein, the smart sensor 120 may also include an external memory 535 with the specific addresses or memory blocks for storing the configuration and calibration data as described above for external memory 335.

FIG. 6 shows an implementation of a particle matter smart sensor 125. In this embodiment, the sensing device 605 may include be a chamber through which air flows, an air flow sensor, and a laser directed through the air flow. Particles in the air flow may reflect the laser and the reflections may be measured by a detector. The signal processor 610 may analyze the output of the detector to determine particle numbers and/or sizes and/or mass. The on board or embedded memory 620 may include programs and instructions that cause the processor 315 to control the operation of the signal processor 610, including the analysis function of the signal processor, to process data specific to the sensing device 605, to further process the data from the signal processor 610, and to convert the data to a fixed bit format such as the normalized 24 bit format. The external memory 635 may include the specific addresses or memory blocks for storing the configuration and calibration data as described above for external memory 335. The control circuitry 630 may receive signals from the signal processor 610 to control a pump regulating the air flow, the air flow sensor, the laser, and the detector.

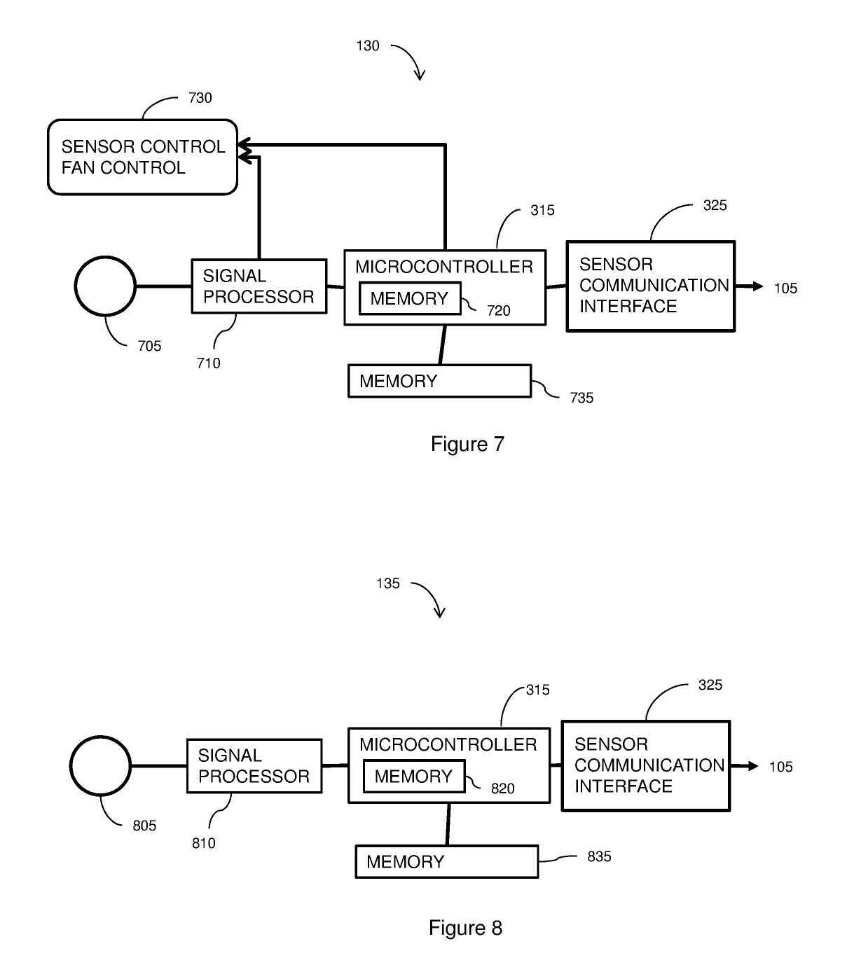

FIG. 7 shows an implementation of an electrochemical smart sensor 130. In this embodiment, the sensing device may be one or more gas sensors 705 for any number of target gasses, or may include other suitable environmental sensors. The signal processor 710 may include an amplifier and an A/D converter. The on board or embedded memory 720 may include programs and instructions that cause the processor 315 to control the operation of the amplifier, A/D converter, and any other function of the signal processor 710, to process gas sensor specific data, to further process the data from the signal processor 610, and to convert the data to a fixed bit format.

The electrochemical smart sensor 130 may also include an external memory 735 with the specific addresses or memory blocks for storing the configuration and calibration data as described above for memory 335.

FIG. 8 shows an implementation of a lux smart sensor 135. In this embodiment, the sensing device 805 may be one or more light sensors, for example, infrared and visible light. The signal processor 810 may include an A/D converter. The on board or embedded memory 820 may include programs and instructions that cause the processor 315 to control the operation of the A/D converter, and any other function of the signal processor 810, to process light sensor specific data, to further process the data from the signal processor 810, and to convert the data to a fixed bit format. Similar to the other smart sensors of the disclosed embodiments, the external memory 835 may also include the specific addresses or memory blocks for storing the configuration and calibration data as described above for external memory 335.

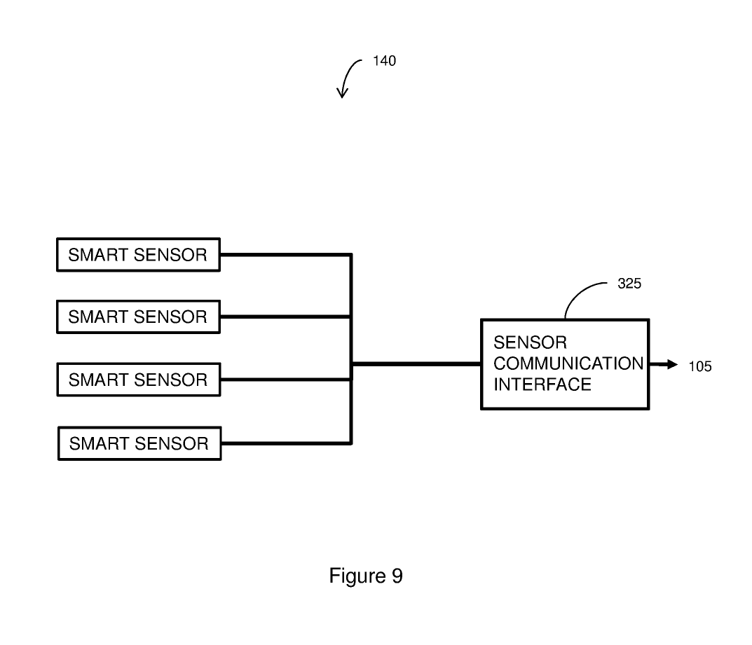

FIG. 9 shows a schematic illustration of an exemplary smart probe 140 connected to the controller 105. The smart probe may be a self-configuring smart probe as disclosed in U.S. patent application Ser. No. 15/788,144, filed 19 Oct. 2017, incorporated by reference in its entirety, and may include one or more smart sensors as described herein, or any other suitable environmental sensors. Similar to the smart sensors, the smart probe 140 may provide data to the controller 105 in a fixed bit format.

In operation, the controller 105 polls the smart sensors 110, 112, 115, 120, 125, 130, 135 and the smart probe 140 and receives information about each smart sensor and the smart probe, including the information at the specific addresses or memory blocks. The controller may enable the operation of each smart sensor and the smart probe, collect data, and display the data and may also send the data to one or more of the wide area or other network 220, the cloud service 225, and the building automation system 230.

In some embodiments, upon the controller 105 enabling the smart sensors 110, 112, 115, 120, 125, 130, 135, each of the microcontrollers 315 may poll their respective external memories 335, 435, 535, 635, 735, 835 and retrieve characteristics of data channels returned by the respective sensing devices, for example, the sensing technologies and sensor types. The microcontrollers may also retrieve a code, algorithm, or other conditioning information for converting the output of the respective sensing devices 305, 405, 505, 605, 705, 805 to a fixed bit format. The microcontrollers 315 may use that conditioning information to convert the respective sensing device channel outputs to the fixed bit format, and may transit the fixed bit format data to the controller 105.

In additional embodiments, upon the controller 105 enabling the smart sensors 110, 112, 115, 120, 125, 130, 135, each of the microcontrollers 315 may poll their respective external memories 435, 535, 635, 735, 835 and retrieve characteristics of data channels returned by the respective sensing devices, for example, the sensing technologies and sensor types. The microcontrollers may also retrieve a code, algorithm, or other conditioning information for converting the outputs of the respective signal processors 410, 510, 610, 710, 810 to a fixed bit format. The controllers may use that conditioning information to convert the respective signal processor outputs for each channel to the fixed bit format, and may transmit the fixed bit format data to the controller 105.

In further embodiments, upon the controller enabling the smart sensors 110, 112, 115, 120, 125, 130, 135, the controller 105 may poll each external memory 335, 350, 435, 535, 635, 735, 835 and retrieve characteristics of data channels returned by the respective sensing devices, for example, the sensing technologies and sensor types. The controller may also retrieve a code, algorithm, or other conditioning information for converting the channel outputs of the respective sensing devices 305, 340, 405, 505, 605, 705, 805 to a fixed bit format. The controller may then poll the enabled smart sensors for the outputs of their respective sensor device outputs, and may use the respective conditioning information to convert the respective sensing device outputs as received to the fixed bit format for further processing and analysis.

While the disclosed embodiments are described in the context of converting the sensing device output, the signal processor output, or both to a 24 bit output, it should be understood that the respective outputs may be utilized as is with no conditioning or may be converted to any other format suitable for use according to the disclosed embodiments.

Various modifications and adaptations may become apparent to those skilled in the relevant arts in view of the foregoing description, when read in conjunction with the accompanying drawings. However, all such and similar modifications of the teachings of the disclosed embodiments will still fall within the scope of the disclosed embodiments.

Various features of the different embodiments described herein are interchangeable, one with the other. The various described features, as well as any known equivalents can be mixed and matched to construct additional embodiments and techniques in accordance with the principles of this disclosure.

Furthermore, some of the features of the exemplary embodiments could be used to advantage without the corresponding use of other features. As such, the foregoing description should be considered as merely illustrative of the principles of the disclosed embodiments and not in limitation thereof.

1. An environmental data collection system comprising:
a controller; and
one or more smart sensors coupled to the controller, each smart sensor comprising a memory, the memory configured to store configuration and calibration data for each data channel output by sensing devices of the smart sensors.

2. The environmental data collection system of claim 1, wherein the one or more smart sensors each comprise a sensor communication interface for communicating with the controller.

3. The environmental data collection system of claim 1, wherein the configuration and calibration data includes conditioning information for converting the data channel outputs to a fixed bit format.

4. The environmental data collection system of claim 3, wherein the fixed bit format is a 24 bit format.

5. The environmental data collection system of claim 3, wherein the one or more smart sensors comprise a signal processor configured to:
use the configuration and calibration data for processing data from each data channel output of the sensing devices; and
use the conditioning information to convert the sensor data for each data channel output to a fixed bit format.

6. The environmental data collection system of claim 5, wherein the signal processor is an analog to digital converter.

7. The environmental data collection system of claim 3, wherein the one or more smart sensors comprise a microcontroller configured to:
use the configuration and calibration data for processing data from each data channel output of the sensing devices; and
use the conditioning information to convert the sensor data for each data channel output to a fixed bit format.

8. The environmental data collection system of claim 1:
wherein the controller comprises a microprocessor and a memory including computer program code, and
wherein executing the computer program code by the microprocessor causes the controller to:
use the configuration and calibration data for processing data from each data channel output of the sensing devices; and
use the conditioning information to convert the sensor data for each data channel output to a fixed bit format.

9. The environmental data collection system of claim 1, further comprising one or more self-configuring smart probes.

10. The environmental data collection system of claim 1, wherein the controller comprises a communication interface to one or more of a wide area or other network, a cloud service, and a building automation system.

11. A method of collecting environmental data comprising:
using a controller to operate one or more smart sensors; and
using a memory on each smart sensor to store configuration and calibration data for each data channel output by sensing devices of each smart sensors.

12. The method of claim 11, wherein the one or more smart sensors each comprise a sensor communication interface for communicating with the controller.

13. The method of claim 11, wherein the configuration and calibration data includes conditioning information for converting the data channel outputs to a fixed bit format.

14. The method of claim 13, wherein the fixed bit format is a 24 bit format.

15. The method of claim 13, comprising using a signal processor of the one or more smart sensors to:
use the configuration and calibration data for processing data from each data channel output of the sensing devices; and
use the conditioning information to convert the sensor data for each data channel output to a fixed bit format.

16. The method of claim 15, wherein the signal processor is an analog to digital converter.

17. The method of claim 13, comprising using a microcontroller of the one or more smart sensors to:
use the configuration and calibration data for processing data from each data channel output of the sensing devices; and
use the conditioning information to convert the sensor data for each data channel output to a fixed bit format.

18. The method of claim 11:
wherein the controller comprises a microprocessor and a memory including computer program code, and
wherein the method further comprises executing the computer program code by the microprocessor to cause the controller to:
use the configuration and calibration data for processing data from each data channel output of the sensing devices; and
use the conditioning information to convert the sensor data for each data channel output to a fixed bit format.
